(19) United States
(12) Patent Application Publication
(10) Pub. No.: US 2009/0302314 A1
(43) Pub. Date: Dec. 10, 2009

(54) P-TYPE ZINC OXIDE THIN FILM AND METHOD FOR FORMING THE SAME

(75) Inventors: Takeshi Kusumori, Aichi (JP); Takahiro Hori, Shizuoka (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: NATIONAL INSTITUTE OF ADV INDUSTRIAL SCI AND TECH, TOKYO (JP)

(21) Appl. No.: 12/306,336

(22) PCT Filed: Jul. 6, 2007
(86) PCT No.: PCT/JP2007/063554

§ 371 Date: Dec. 23, 2008

(30) Foreign Application Priority Data
Jul. 6, 2006 (JP) 2006-187266
Jul. 4, 2007 (JP) 2007-176736

(51) Int. Cl. H01L 33/00; H01L 29/22; H01L 21/34

(52) U.S. Cl. 257/43; 438/104; 257/E29.094; 257/E21.459; 257/E33.019

(57) ABSTRACT

The present invention provides a p-type zinc oxide thin film that is clearly shown to be a p-type semiconductor based on the magnetic field dependence of the Hall voltage in the measurement of the Hall effect using a Hall bar, as well as a method for producing such a thin film with good reproducibility, and a light-emitting element thereof, and the present invention relates to the method for producing a p-type zinc oxide semiconductor thin film, for which combination is effected between a high temperature annealing step for activating a p-type dopant added to a zinc oxide thin film in order to develop the p-type semiconductor properties of zinc oxide or irradiating the thin film with an active species of p-type dopant to dope the film while the p-type dopant is active, and a low temperature annealing step in an oxidizing atmosphere, whereby conversion to a p-type semiconductor is realized, and relates to a p-type zinc oxide thin film thus produced using this method and a light-emitting element thereof, the present invention thereby affording a highly reliable p-type zinc oxide thin film, method of producing the same, and blue light-emitting element thereof.

### TECHNICAL FIELD

The present invention relates to a p-type zinc oxide thin film and a method of producing the same, and in particular to a p-type zinc oxide thin film which is necessary in the basic technology for using zinc oxide to produce light-emitting elements related to light of wavelengths ranging from blue to across the UV spectrum.

### BACKGROUND

Attention has turned to zinc oxide as an alternative material for gallium nitride which is widely used at present as material for light-emitting elements from blue to the UV range. Zinc oxide is an abundant, inexpensive resource in the world, and is so benign that it can be used in cosmetics. Unlike gallium nitride, zinc oxide has the advantage of ready synthesis, such as yielding monocrystalline wafers and also allowing films of uniaxial crystal orientation to be formed on glass substrates. Zinc oxide is also capable of more stable lasing than gallium nitride. Based on these advantages, the ability to produce a light-emitting element with zinc oxide could result in the promise of energy conservation, conservation of resources, and further expansion of related industry.

Research for converting zinc oxide thin films to p-type semiconductors first focused on improving the crystallinity of thin films (Patent Documents 1 to 3, Non-Patent Document 1). Approaches attempting to bring about p-type conversion through the addition of impurities serving as acceptors were then adopted (Patent Document 4, Non-Patent Document 2). Much success was achieved with this technique in conventional silicon semiconductors and compound semiconductors. Virtually all research and development on p-type conversion of zinc oxide thin films therefore proceeded along this path. However, there are virtually no examples capable of clearly showing p-type semiconductor electrical properties based on the magnetic field dependence of the Hall voltage when determining the Hall effect using a Hall bar, for example, and it is, in fact, extremely difficult to produce a p-type zinc oxide thin film with good reproducibility.

Methods based on simultaneous doping with p-type and n-type dopants are another approach aimed at p-type conversion of zinc oxide. Nitrogen is considered a desirable dopant for p-type conversion in order to produce acceptor levels at shallow positions in zinc oxide. However, it is difficult to dope zinc oxide with nitrogen, and furthermore, films doped only with nitrogen have a high electrical resistivity of 100 Ω·cm or more, making them impractical.

By contrast, it has been reported that a p-type zinc oxide thin film with a high nitrogen concentration and an electrical resistivity of no more than 100 Ω·cm can be produced when it is doped with gallium, aluminum, boron, or hydrogen, which are n-type dopants, at the same time as nitrogen (Patent Document 5). A research article (Non-Patent Document 3) on this has attracted attention, and further studies on simultaneous doping with nitrogen and an n-type dopant (gallium) have been carried out by various groups, but it has been pointed out that the reproducibility is very poor (Non-Patent Document 4).

Many reports have thus far claimed success in achieving p-type conversion of zinc oxide thin films, but what has been presented as evidence was that a laminated structure was produced with zinc oxide thin film, where the current-voltage properties exhibited rectification properties similar to p-n junctions (Non-Patent Documents 5 and 6), or results in the form of numerical figures in the measurement of the Hall effect based on the van der Pauw method (Patent Document 6, Non-Patent Documents 6 to 8).

However, the electrical properties obtained with laminated structures are known to significantly affect the interface between electrodes and semiconductor thin films or the interface between laminated semiconductor thin films; for example, it is known that rectification properties similar to p-n properties are exhibited upon the formation of a Schottky barrier between semiconductors and electrodes. It has also been pointed out that new interfacial layers can be formed as a result of interracial reaction between semiconductor thin layers, thus resulting in the manifestation of p-type electrical properties (Patent Document 7).

Tests for clearly showing that zinc oxide thin films are p-type semiconductors comprise measurement of the Hall effect, and verification by the same methods are imperative (Non-Patent Document 9). Measurement of the Hall effect includes methods of measurement in which the thin film is processed into a Hall bar, and the van der Pauw method. In the van der Pauw method, the particular form of the sample does not matter as long as the sample is simply connected (that is, there are no holes in the sample or no insulator regions are included). Electrodes are also attached in four locations to the sample, and results such as the conduction type or carrier concentration can be obtained through calculations based on the results of a total of 8 times of voltage measurements.

The van der Pauw method is thus widely used to evaluate the physical properties of semiconductors because the measurements are simple. The van der Pauw method has even come to be widely used to measure the Hall effect in verifying p-type conversion of zinc oxide thin films. However, this method requires ohmic electrodes of extremely small surface area to be attached, and the film quality must also be uniform. Particularly in the case of zinc oxide thin films, the electrical conductivity tends to be uneven in some places, and it has been pointed out that this is why results indicating a p-type semiconductor may be obtained even though the sample is an n-type semiconductor in the van der Pauw method. In addition, because the Hall voltage is very low, the measured results are affected by noise (Non-Patent Document 9). The interpretation of results obtained by the van der Pauw method therefore requires considerable caution.

Another problem with results obtained by the van der Pauw method includes the significant differences in the results for carrier concentration or mobility between research groups (Non-Patent Document 9). Seong-Ju Park's group in Korea has reported obtaining a p-type zinc oxide thin film with a Hall concentration of 10¹⁹/cm³ in an embodiment in the said Patent Document 7, and a Hall concentration of 1.7×10¹⁹/cm³ has been reported as a result of the measurement of the Hall effect by the van der Pauw method in the said Non-Patent Document 8.

Many other successful examples of p-type zinc oxide thin films have been reported with a high Hall concentration of 10¹⁹/cm³ or more (Patent Documents 8 and 9, and Non-Patent Documents 6 and 7). And p-type zinc oxide thin films with an extremely high Hall concentration of ≦8×10²¹/cm³ have been reported in the examples of yet other patent documents (Patent Document 10). However, based on theoretical calculations and the like, results indicating a high Hall concentration of 10¹⁹/cm³ or more such as these reports of p-type zinc oxide thin films are considered unrealistic (Non-Patent Document 10).

These problems are due to the use of the van der Pauw method for measuring the Hall effect in zinc oxide thin films. Although it has been claimed repeatedly in academic institutions, research conferences, and the like that verification of the measurement of the Hall effect using a Hall bar is essential for clearly demonstrating a p-type semiconductor, there are thus far virtually no examples definitively demonstrating p-type conversion by measurement using a Hall bar. In fact, virtually all of the results indicating samples to be p-type semiconductors in measurement of the Hall effect are based on the van der Pauw method. By contrast, an object of the present invention is to provide a reliable p-type zinc oxide thin film of quality which is clearly shown to be a p-type semiconductor based on the magnetic field dependence of the Hall voltage in measurement of the Hall effect using a Hall bar.

Patent Document 1: Patent Specification No. 3423896

Patent Document 2: JP-A-2005-108869

Patent Document 3: JP-A-2004-221352

Patent Document 4: JP-A-2005-223219

Patent Document 5: Patent Specification No. 3540275

Patent Document 6: JP-A-2002-105625

Patent Document 7: JP-A-2005-39172

Patent Document 8: JP-A-2002-289918

Patent Document 9: JP-A-2001-48698

Patent Document 10: JP-A-2001-72496

Non-Patent Document 1: Y. Chen, D. M. Bagnall, H. J. Koh, K. T. Park, K. Hiraga, Z. Zhu, T. Yao: J. Appl. Phys. 84 (1998) 3912

Non-Patent Document 2: A. Tsukazaki, A. Ohtomo, T. Onuma, M. Ohtani, T. Makino, M. Sumiya, K. Ohtani, S. F. Chichibu, S. Fuke, Y. Segawa, H. Ohno, H. Koinuma, M. Kawasaki: Nature Materials 4 (2005) 42

Non-Patent Document 3: T. Yamamoto, H. K. Yoshida: Jpn. J. Appl. Phys. 38 (1999) L166

Non-Patent Document 4: K. Nakahara, H. Takasu, P. Fons, A. Yamada, K. Iwata, K. Matsubara, R. Hunger, S. Niki: J. Cryst. Growth 237-239 (2002) 503

Non-Patent Document 5: Y. R. Ryu, T. S. Lee, J. H. Leem, H. W. White: Appl. Phys. Lett. 83 (2003) 4032

Non-Patent Document 6: M. Joseph, H. Tabata, H. Saeki, K. Ueda, T. Kawai: Physica B 302-303 (2001) 140

Non-Patent Document 7: M. Joseph, H. Tabata, T. Kawai: Jpn. J. Appl. Phys. 38 (1999) L1205

Non-Patent Document 8: K. K. Kim, H. S. Kim, D. K. Hwang, J. H. Lim, S. J. Park: Appl. Phys. Lett. 83 (2003) 63

Non-Patent Document 9: D. C. Look, B. Claflin: Phys. Stat. Sol. B 241 (2004) 624

Non-Patent Document 10: D. C. Look, D. C. Reynolds, C. W. Litton, R. L. Jones, D. B. Eason, G. Cantwell: Appl. Phys. Lett. 81 (2002) 1830

In view of the foregoing, the inventors conducted extensive research in light of the conventional technology noted above in order to develop a method by which a reliable p-type zinc oxide thin film could be produced in a simple manner with good reproducibility on a transparent substrate such as a sapphire substrate. The formation of a thin film with good crystallinity and high quality is vital in order to improve the properties of a device.

However, the inventors found that what significantly affects the conversion of zinc oxide into a p-type semiconductor is not the film crystallinity, but the excess zinc in the lattice, and perfected the present invention upon successfully producing a reliable p-type zinc oxide thin film with good reproducibility using an approach completely unlike conventional methods by activating a dopant through the high temperature annealing of a zinc oxide thin film containing impurities as acceptors, or by irradiating the film with an active species of dopant to dope the film while the p-type dopant was in an activated state, and then annealing the film at a low temperature, thereby reducing the excess zinc in the film which is a cause of the n-type.

### DISCLOSURE OF THE INVENTION

An object of the present invention is to provide a p-type zinc oxide thin film which is necessary for producing a light-emitting element of zinc oxide formed on a transparent substrate such as a sapphire substrate, a method for its production, and a light-emitting element thereof, and a further object of the present invention is to provide a carrier control technique which can serve as the basis for techniques related to transparent semiconductor films or wide band gap semiconductor electronics in which zinc oxide is employed.

The present invention devised to solve the abovementioned problems is constituted of the following technical means.

(1) A p-type zinc oxide semiconductor thin film, characterized in that 1) a p-type dopant added to the thin film is activated, 2) excess zinc is removed, 3) the inclination in a graph of the Hall voltage-magnetic field properties in results for Hall effect measurements clearly reveals the film to be a p-type semiconductor, and 4) whereby conversion to a p-type semiconductor is realized.

(2) The p-type zinc oxide semiconductor thin film according to (1) above, characterized in that the field effect dependence of the Hall voltage in measurement of the Hall effect using a Hall bar clearly reveals that the film is a p-type semiconductor.

(3) The p-type zinc oxide semiconductor thin film according to (1) above, comprising a substrate, the p-type zinc oxide semiconductor thin film being characterized in that the substrate is a glass substrate, sapphire substrate, zinc oxide monocrystalline substrate, or a substrate having a zinc oxide monocrystalline thin film on a surface layer thereof, regardless of crystal symmetry or compatibility of lattice constant with the p-type zinc oxide thin film to be formed thereon.

(4) The p-type zinc oxide semiconductor according to (1) above, characterized in that the zinc oxide thin film converted to a p-type is a monocrystalline (epitaxial) thin film or polycrystalline thin film.

(5) The p-type zinc oxide semiconductor thin film according to (1) above, characterized in that the Hall concentration is at least 1×10¹⁵ cm⁻³.

(6) The p-type zinc oxide semiconductor thin film according to (1) above, characterized in that the electrical resistivity is not more than 100 Ω·cm.

(7) A method for producing a p-type zinc oxide semiconductor thin film, characterized by combining a step for activating a p-type dopant added to a zinc oxide thin film in order to develop p-type semiconductor properties of zinc oxide, and a step for low temperature annealing in an oxidizing atmosphere, whereby conversion to a p-type semiconductor is realized.

(8) The method for producing a p-type zinc oxide semiconductor thin film according to (7) above, characterized in that the thin film is annealed at a high temperature of 700 to 1200° C. in an inert gas atmosphere or nitrogen gas atmosphere as the step for activating the p-type dopant added to the zinc oxide thin film.

(9) The method for producing a p-type zinc oxide semiconductor thin film according to (7) above, characterized in that the substrate surface is irradiated with an active species of dopant so that the thin film is doped while the p-type dopant is activated during the step of growing the zinc oxide thin film as the step for activating the p-type dopant added to the zinc oxide thin film.

(10) The method for producing a p-type zinc oxide semiconductor thin film according to (7) above, characterized in that the thin film is annealed at a low temperature of 200 to 700° C. in an oxidizing atmosphere as the low temperature annealing step.

(11) The method for producing a p-type zinc oxide semiconductor thin film according to (7) above, characterized in that nitrogen is used as the p-type dopant for converting the zinc oxide to a p-type, and is added either alone or with another element.

(12) A light-emitting element, characterized by comprising a structure in which the p-type zinc oxide thin film according to any of (1) to (6) is formed on a substrate.

(13) The light-emitting element according to (12) above, comprising a structure in which a monocrystalline (epitaxial) thin film or polycrystalline thin film is formed on a glass substrate, sapphire substrate, zinc oxide monocrystalline substrate, or a substrate having a zinc oxide crystalline thin film on a surface thereof.

The present invention is illustrated in greater detail below.

The present invention is a reliable p-type zinc oxide semiconductor thin film, characterized in that a p-type dopant added to the thin film is activated, excess zinc is removed, and the inclination in a graph of the Hall voltage-magnetic field properties in the results for Hall effect measurements clearly reveals the film to be a p-type semiconductor, thereby resulting in the conversion to a p-type semiconductor.

In preferred embodiments of the present invention, the film is clearly shown to be a p-type zinc oxide thin film based on the magnetic field dependence of the Hall voltage in Hall effect measurements using a Hall bar; the film has a substrate, the substrate being a glass substrate, sapphire substrate, zinc oxide monocrystalline substrate, or a substrate having a zinc oxide monocrystalline thin film as the surface layer, regardless of the crystal symmetry or the compatibility of the lattice constant with the p-type zinc oxide thin film to be formed thereon; the zinc oxide thin film to be converted to a p-type is a monocrystalline (epitaxial) thin film or polycrystalline thin film; and the Hall concentration is at least 1×10¹⁵ cm⁻³.

The present invention is also a method for producing a p-type zinc oxide semiconductor thin film, characterized by combining a step for activating a p-type dopant added to a zinc oxide thin film in order to develop the p-type semiconductor properties of zinc oxide, and a step for low temperature annealing in an oxidizing atmosphere, thereby resulting in the conversion to a p-type semiconductor.

In preferred embodiments of the invention, as the step for activating the p-type dopant added to the zinc oxide thin film, the thin film is annealed at an elevated temperature of 700 to 1200° C. in an inert gas atmosphere or nitrogen gas atmosphere, or an active species of p-type dopant is irradiated during film formation so that the film is doped while the p-type dopant is active; the thin film is annealed at a low temperature of 200 to 700° C. in an oxidizing atmosphere as the low temperature annealing step; and nitrogen is used as the p-type dopant for converting the zinc oxide to a p-type, and this is added either alone or at the same time as another element.

The present invention is also a light-emitting element, characterized by comprising a structure in which the above p-type zinc oxide thin film is formed on a substrate. In a preferred embodiment of the present invention, the light-emitting element has a structure in which a monocrystalline (epitaxial) thin film or polycrystalline thin film is formed on a glass substrate, sapphire substrate, zinc oxide monocrystalline substrate, or a substrate having a zinc oxide crystalline thin film on the surface.

In the present invention, a p-type dopant added to a zinc oxide thin film is activated by elevated temperature annealing or the zinc oxide thin film is doped while the p-type dopant is in an activated state, and the thin film is then subjected to low temperature annealing in an oxidizing atmosphere to reduce the level of excess zinc which can be a cause of n-type carriers, thereby allowing a highly reliable p-type zinc oxide thin film to be produced and provided.

Preferred examples of methods for producing a zinc oxide thin film include pulse laser deposition, MBE (molecular beam epitaxy), sputtering, and CVD (chemical vapor deposition), but the method for producing a thin film of zinc oxide to which a p-type dopant has been added is not limited to these specific film deposition methods, and any suitable method of film deposition can be used.

Nitrogen is used as the element added as the p-type dopant. Nitrogen sources include nitrogen gas or gas mixtures of nitrogen gas and oxygen gas, as well as gases that contain nitrogen, such as nitrous oxide gas and ammonia gas, which can similarly be used. As the nitrogen source, active species of nitrogen can also be used in such a way that the film will be doped while the nitrogen is in an activated state. When this element is added, it is possible to either add nitrogen alone into the thin film or to simultaneously add another element (such as phosphorus, arsenic, gallium, magnesium, aluminum, boron, and hydrogen to increase the nitrogen doping level) in order to increase the concentration of nitrogen in the thin film. Any element may be added simultaneously, provided that it does not compromise the p-type conversion of the zinc oxide thin film. Phosphorus is a desirable example of such an element.

The thin film is annealed at an elevated temperature of 700 to 1200° C. in an inert gas atmosphere or nitrogen gas atmosphere in order to activate the p-type dopant that has been added to the thin film of zinc oxide. Examples of specific methods of annealing include, but are not limited to, methods such as heating in electric furnaces, optical irradiation heating with IR lamp light, induction heating, electron bombardment heating, and electrical heating, but heating in an electric furnace is desirable for obtaining uniform heat distribution.

Nitrogen gas or an inert gas such as argon is used as the atmosphere gas. The annealing treatment time ranges from several seconds to dozens of minutes. The annealing time is shorter when the treatment is done at elevated temperature; a zinc oxide thin film exhibiting p-type electrical properties can be obtained by 15 seconds of annealing at 1000° C. in the case of a zinc oxide thin film produced on a sapphire substrate, for example.

To dope a thin film of zinc oxide while the p-type dopant is in an activated state, the film is deposited as the surface of the substrate is irradiated with an active species of nitrogen (nitrogen atoms, etc.) produced by converting a gas that contains nitrogen atoms into a plasma. Specific examples of methods for producing a plasma include, but are not limited to, RF (radio frequency) inductive coupling or microwave ECR (electron cyclotron resonance), but RF (radio frequency) inductive coupling, which produces fewer ion species that can damage thin films is preferably used.

As a result of extensive research to obtain a zinc oxide thin film exhibiting p-type electrical properties, the inventors found that low temperature annealing in an oxidizing atmosphere is necessary, after the activation of the p-type dopant, in order to eliminate excess zinc that can result in n-type semiconductor electrical properties, that there is an increase of excess zinc as a result of the partial deficit of oxygen in the zinc oxide thin film when elevated temperature annealing is carried out in an oxygen-free atmosphere in order to activate the p-type dopant, that the excess zinc oxide functions as a donor, causing the film to become an n-type semiconductor, and that the film is doped while the p-type dopant is in an activated state when the film is deposited as the substrate surface is irradiated with an active species of p-type dopant.

Here, in the present invention, the annealing is preferably done for a long period of time in an oxidizing atmosphere such as oxygen or air at 200 to 700° C., for example, to reduce the excess zinc which increases as a result of the partial deficit of oxygen in the zinc oxide thin film after the activation of the p-type dopant. The annealing time ranges from dozens of minutes to several hours, but the time is preferably as long as possible in order to reduce the excess zinc. A zinc oxide thin film treated in the above manner will exhibit magnetic field dependence of the Hall voltage which is characteristic of p-type semiconductors when the Hall effect is measured using a Hall bar.

According to the present invention, the conversion of zinc oxide to a p-type is not very much affected by the film crystallinity, making it possible to readily achieve p-type conversion of a zinc oxide thin film with relatively poor crystallinity produced on a substrate such as a sapphire substrate, for example, having a different lattice constant than zinc oxide. According to the present invention, it is possible to obtain a p-type zinc oxide thin film having low electrical resistivity when the treatment of the invention is carried out, even on films doped only with nitrogen, without any need for simultaneously adding an n-type dopant, in order to produce a p-type zinc oxide thin film having a low electrical resistivity of no more than 100 Ω·cm.

Examples of elements that are added simultaneously in order to increase the concentration of nitrogen in thin films include gallium, aluminum, boron, and hydrogen, but these are not necessary; for example, phosphorus can be used to increase the nitrogen concentration in the thin film and obtain a p-type zinc oxide thin film. In the present invention, the species is not limited and can be similarly used, provided that it is an element added to increase the concentration of nitrogen in the thin film. The p-type zinc oxide thin film provided by the present invention is clearly shown to be a p-type semiconductor based on the magnetic field dependence of the Hall voltage in measurement of the Hall effect using a Hall bar.

The present invention provides a p-type zinc oxide thin film, its method of production, and a light-emitting element thereof, wherein the p-type zinc oxide semiconductor thin film is characterized in that a p-type dopant added to the thin film is in an activated state, excess zinc is removed, and the inclination in a graph of the Hall voltage-magnetic field properties in the results for Hall effect measurements clearly reveals the film to be a p-type semiconductor, thereby resulting in the conversion to a p-type semiconductor.

Although various well known techniques have been conventionally reported as successful examples of p-type zinc oxide thin films, the van der Pauw method was employed in all of them to measure the Hall effect, and the high Hall concentrations are considered to be unrealistic based on theoretical calculations, etc. By contrast, the inclination in a graph of the Hall voltage-magnetic field properties in the results of measurement of the Hall effect using a Hall bar can demonstrate that conversion to a p-type semiconductor has been achieved in the present invention, which poses considerable technical significance in terms of making it possible to produce and provide highly reliable p-type zinc oxide thin films, as well as light-emitting elements thereof, which are substantially different from conventional materials.

Because the inclination in a graph of the Hall voltage-magnetic field properties in the results of Hall effect measurements using a Hall bar show the p-type zinc oxide thin film in the invention to be a p-type semiconductor, this can be used as an indicator to clearly differentiate (distinguish) the film from conventional materials. As noted in the Background Art section above, several successful examples of p-type zinc oxide thin film have been conventionally reported, but none of them report proving the conventional materials to be p-type semiconductors based on the inclination in a graph of the above Hall voltage-magnetic field properties. The present invention is useful in terms of making it possible to provide a light-emitting element of a highly reliable p-type zinc oxide thin film which can serve as an alternative to gallium nitride which is widely used at present for blue light-emitting elements.

The present invention affords the following effects.

(1) It is possible to provide a p-type zinc oxide thin film, as well as its method of production, which is clearly shown to be a p-type semiconductor based on the magnetic field dependence of the Hall voltage in the measurement of the Hall effect using a Hall bar.

(2) It is possible to provide a method, as well as light-emitting elements formed thereby, in which a p-type zinc oxide thin film is formed on a transparent substrate such as a sapphire substrate which is necessary when using zinc oxide to produce light-emitting elements that emit light with wavelengths ranging from blue to across the UV ray spectrum.

(3) It is possible to provide a carrier control technique which can serve as the basis for wide band gap semiconductor electronics techniques in which zinc oxide is employed.

(4) It is possible to provide a highly reliable p-type zinc oxide light-emitting element that can serve as an alternative to gallium nitride which is widely used for blue light-emitting elements.

### BRIEF DESCRIPTION OF THE DRAWINGS

FIG. 1 illustrates the positions of the electrodes and the configuration of the Hall bar used to measure the Hall effect in order to show that the film is a p-type zinc oxide thin film;

FIG. 2 illustrates the magnetic field dependence of the Hall voltage based on measurement of the Hall effect in a sample which was obtained, according to one embodiment of the invention, when a zinc oxide thin film produced in a nitrogen atmosphere using a zinc oxide target was annealed for 30 sec in an argon atmosphere at 900° C. (elevated temperature annealing) and then annealed for 1.5 hours at 550° C. in an oxygen atmosphere (low temperature annealing);

FIG. 3 illustrates the spectra for N1s bond energy determined by X-ray photoelectron spectrometry in (1) zinc oxide thin films produced in a nitrogen atmosphere using zinc oxide targets, (2) zinc oxide thin films produced in a nitrogen atmosphere using zinc oxide targets to which 2 mol % phosphorus had been added, (3) zinc oxide thin films produced in a nitrous oxide atmosphere using zinc oxide targets, and (4) zinc oxide thin films produced in a nitrous oxide atmosphere using zinc oxide targets to which 2 mol % phosphorus had been added, according to one embodiment of the invention;

FIG. 4 illustrates the magnetic field dependence of the Hall voltage based on measurement of the Hall effect in a sample which was obtained, according to one embodiment of the invention, when a zinc oxide thin film produced in a nitrous oxide atmosphere using a zinc oxide target to which 2 mol % phosphorus had been added was annealed for 30 sec in an argon atmosphere at 900° C. (elevated temperature annealing) and then annealed for 3.5 hours at 500 to 550° C. in an oxygen atmosphere (low temperature annealing);

FIG. 5 illustrates the magnetic field dependence of the Hall voltage based on measurement of the Hall effect in a sample which was obtained, according to one embodiment of the invention, when a zinc oxide thin film produced in a nitrous oxide atmosphere using a zinc oxide target to which 2 mol % phosphorus had been added was annealed for 30 sec in a nitrogen atmosphere at 900° C. (elevated temperature annealing) and then annealed for 3.5 hours at 500 to 550° C. in an oxygen atmosphere (low temperature annealing);

FIG. 6 illustrates the magnetic field dependence of the Hall voltage based on measurement of the Hall effect in (1) a sample which was obtained, according to one embodiment of the invention, when a zinc oxide thin film produced in a nitrous oxide atmosphere using a zinc oxide target to which 2 mol % phosphorus had been added was annealed for 1 min in an argon atmosphere at 900° C. (elevated temperature annealing) and then annealed for 3 hours at 550° C. in an oxygen atmosphere (low temperature annealing), and (2) a sample obtained when the thin film was annealed for 2 min in a nitrogen atmosphere at 900° C. (elevated temperature annealing) and then annealed for 3 hours at 550° C. in an oxygen atmosphere (low temperature annealing);

FIG. 7 illustrates the magnetic field dependence of the Hall voltage based on measurement of the Hall effect in a sample which was obtained, according to one embodiment of the invention, when a zinc oxide thin film produced in a nitrous oxide atmosphere using a zinc oxide target to which 2 mol % phosphorus had been added was annealed for 30 sec in a nitrogen atmosphere at 900° C. (elevated temperature annealing);

FIG. 8 illustrates X-ray diffraction patterns based on 2θ-ω scanning for a zinc oxide thin film produced in the nitrous oxide atmosphere by pulse laser deposition, according to one embodiment of the invention, using a zinc oxide target to which 2 mol % phosphorus had been added;

FIG. 9 illustrates the current-voltage characteristics of p-n junctions in a p-type zinc oxide thin film according to one embodiment of the invention laminated with a gallium-doped n-type zinc oxide thin film;

FIG. 10 illustrates the optical spectra for active species of nitrogen produced by the introduction of nitrogen at a flow rate of 0.3 sccm into a PBN (pyrolytic boron nitride) discharge tube and the subsequent application of 300 W output RF (radio frequency) during the process for doping a zinc oxide thin film while the nitrogen serving as the p-type dopant was in an activated state according to one embodiment of the invention; and

FIG. 11 illustrates the magnetic field dependence of the Hall voltage based on measurement of the Hall effect in a sample which was obtained, according to one embodiment of the invention, upon 3 hours of annealing at 550° C. in an oxygen atmosphere (low temperature annealing) of a zinc oxide thin film that was produced as the substrate surface was irradiated with active species of nitrogen produced through the application of 300 W output RF (radio frequency) in order to dope the zinc oxide thin film while the nitrogen serving as the p-type dopant was in an activated state.

### BEST MODE FOR CARRYING OUT THE INVENTION

The present invention is described in detail based on the following embodiments, but the invention is in no way limited by the following examples.

### Example 1

This example is a detailed illustration, based on the drawings, of an embodiment of a p-type zinc oxide thin film obtained through the production of a zinc oxide thin film, to which nitrogen is added or nitrogen and phosphorus are simultaneously added, on a sapphire substrate by pulse laser deposition, followed by activation of the p-type dopant by elevated temperature annealing and then low temperature annealing.

The zinc oxide thin film is produced by pulse laser deposition using the fourth high frequency (wavelength 266 nm) of a Nd:YAG laser. The starting material zinc oxide target was zinc oxide powder (purity: 99.999%) which had been compression molded into pellets and sintered, and a mixture of zinc oxide powder and red phosphorus (purity: 99.9999%) which had been compression molded into pellets. The target was set up facing the substrate heater inside a vacuum vessel.

A sapphire monocrystalline substrate was secured to the surface of the substrate heater. The distance between the target and substrate was 30 mm. A vacuum was created in the vessel using a rotary pump and turbo-molecular pump, and after a pressure of 10⁻⁴ to 10⁻⁵ Pa had been reached, the substrate heater was heated to 500° C. to heat the substrate. The target surface was then irradiated with pulse laser light focused through a lens to vaporize the target and allow a zinc oxide thin film to be deposited on the substrate. The laser oscillating frequency was 2 Hz, and the energy was 40 to 42 mJ/pulse. To dope the film with nitrogen as an acceptor, nitrogen gas or nitrous oxide gas was introduced to 10 Pa inside the vacuum vessel to grow the film, the gas was then further introduced to 50 Pa, and the substrate temperature was then lowered to room temperature.

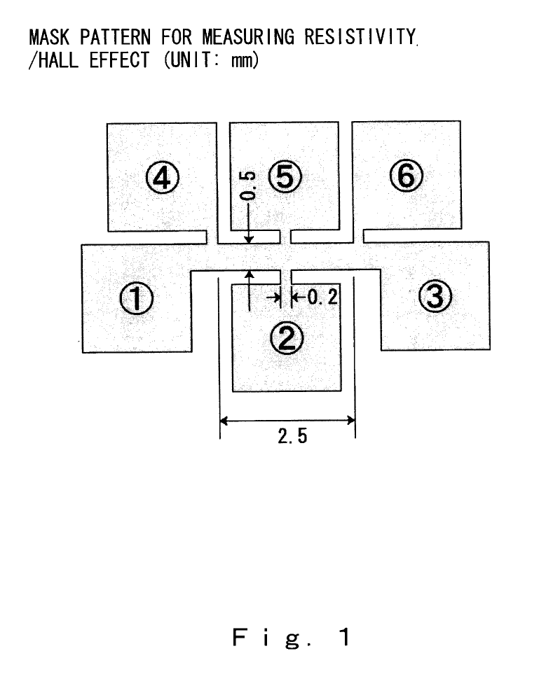

The Hall effect was measured using a Hall bar to clearly show whether the film that had been produced was a p-type semiconductor or n-type semiconductor. This is described in detail below. FIG. 1 illustrates the configuration of the Hall bar used in the measurement (mask pattern for measuring resistivity/Hall effect). The zinc oxide thin films that had been produced were processed into the pattern in FIG. 1 using optical lithography and wet chemical etching. A photomask was used to transfer the pattern in FIG. 1 to a photoresist (photosensitive material) applied on the zinc oxide thin films that had been produced, and the parts of the film other than the pattern were then etched away with dilute nitric acid to form the Hall bar.

This was set up in a bakelite sample holder produced for Hall effect measurements, and gold wire was bonded with indium to the square electrodes indicated by numerals 1 to 6 in FIG. 1, giving current/voltage terminals. As zinc oxide is photoconductive, the sample was shielded to minimize the influence of this effect, and measurements were taken after waiting for the thin film resistivity to reach a virtually constant level. A magnetic field (H) was applied by sweeping a normal conduction electromagnet within a range from 10 kOe to −10 kOe perpendicular to the plane of the page.

Current (I) was then applied across electrodes 1 and 3, and the Hall voltage (V_{H}) appearing between electrodes 2 and 5 was measured. The inclination of a graph of the applied magnetic field (H) and the Hall voltage (V_{H}) at this time allowed the conduction type of the sample to be determined. Here, the inclination in a graph of the Hall voltage-magnetic field properties is positive for p-type semiconductors and is negative for n-type semiconductors. Current was also applied across electrodes 1 and 3 voltage, and the voltage produced between electrodes 4 and 6 was measured to determine the film resistivity. Here, a current source with a high input/output impedance of 100 TΩ and a voltage meter were used to measure the Hall effect and resistivity.

Hall voltage-magnetic field properties clearly characteristic of p-type semiconductors were found, as a result of the p-type dopant activation and low temperature annealing treatment of the invention, upon measurement of the Hall effect using the above Hall bar in the zinc oxide thin films to which nitrogen had been added or to which nitrogen and phosphorus had been simultaneously added. On the other hand, samples which had not been treated according to the invention all exhibited the properties of n-type semiconductors, or had extremely high resistivity and exhibited no clear conduction type. Several examples are given below. Table 1 summarizes the resistivity, carrier concentration, mobility, and conduction type determined by measurement of the Hall effect described above.

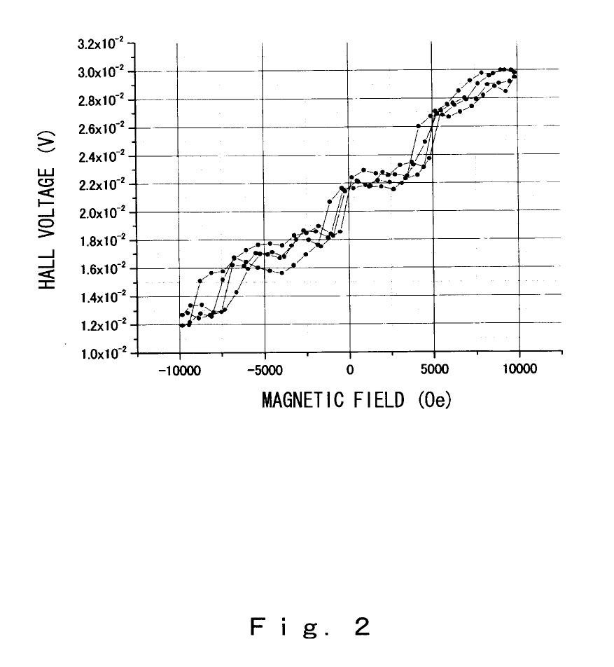

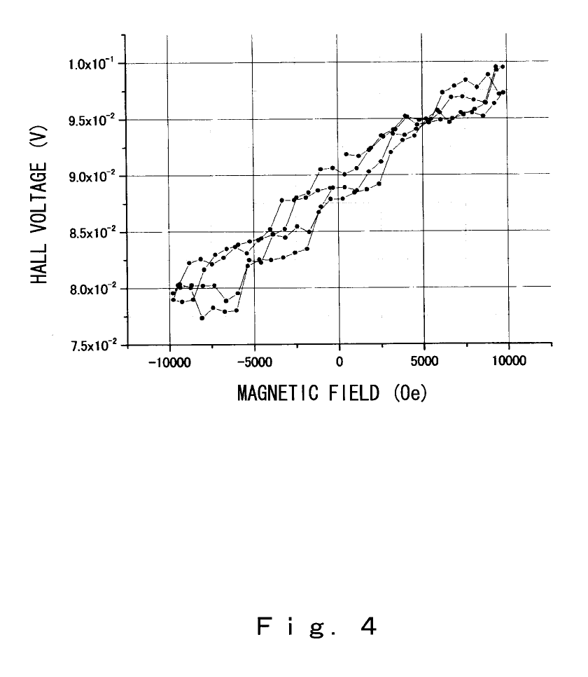

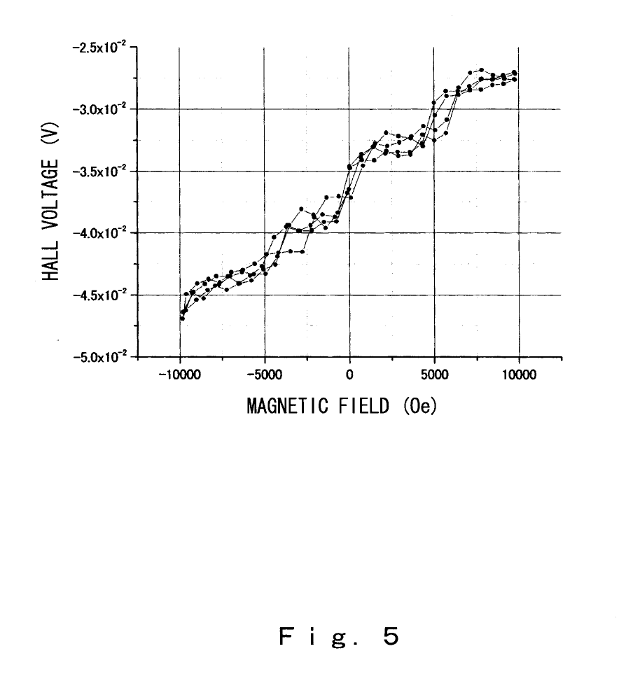

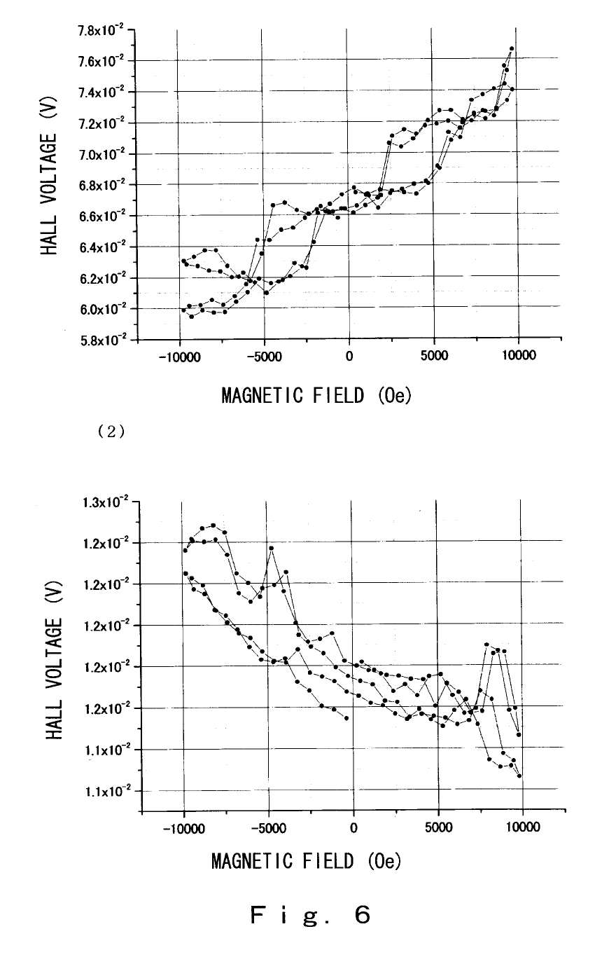

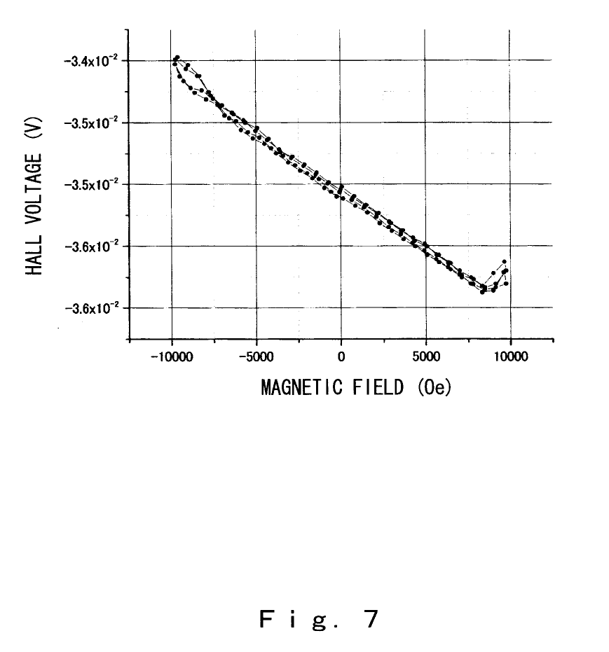

TABLE 1

| | Resistivity | Carrier conc. | Mobility | Conduction |
|---|---|---|---|---|
| Graph | Ω · cm | cm⁻³ | cm²/V · s | type |
| FIG. 2 | 43.8 | 4.37 × 10¹⁵ | 32.6 | p type |
| FIG. 4 | 86.4 | 4.40 × 10¹⁵ | 16.4 | p type |
| FIG. 5 | 32.3 | 4.95 × 10¹⁵ | 39.0 | p type |
| FIG. 6-(1) | 79.6 | 3.44 × 10¹⁵ | 22.9 | p type |
| FIG. 6-(2) | 18.1 | 7.73 × 10¹⁶ | 4.68 | n type |
| FIG. 7 | 5.10 | 3.04 × 10¹⁷ | 4.02 | n type |

FIG. 2 shows the result for the measurement of the Hall effect in samples that were obtained when zinc oxide thin films produced using zinc oxide targets at a substrate temperature of 600° C. in a nitrogen atmosphere were annealed for 30 sec at 900° C. in an argon atmosphere (elevated temperature annealing) and then annealed for 1.5 hours at 550° C. in an oxygen atmosphere (low temperature annealing). The inclination in the graph of the Hall voltage-magnetic field properties is positive and thus clearly shows the film to be a p-type semiconductor. A p-type zinc oxide thin film with a low resistivity of 43.8 Ω·cm was also obtained even when doped simultaneously with other elements. The Hall concentration at this time was 4.37×10¹⁵ cm⁻³.

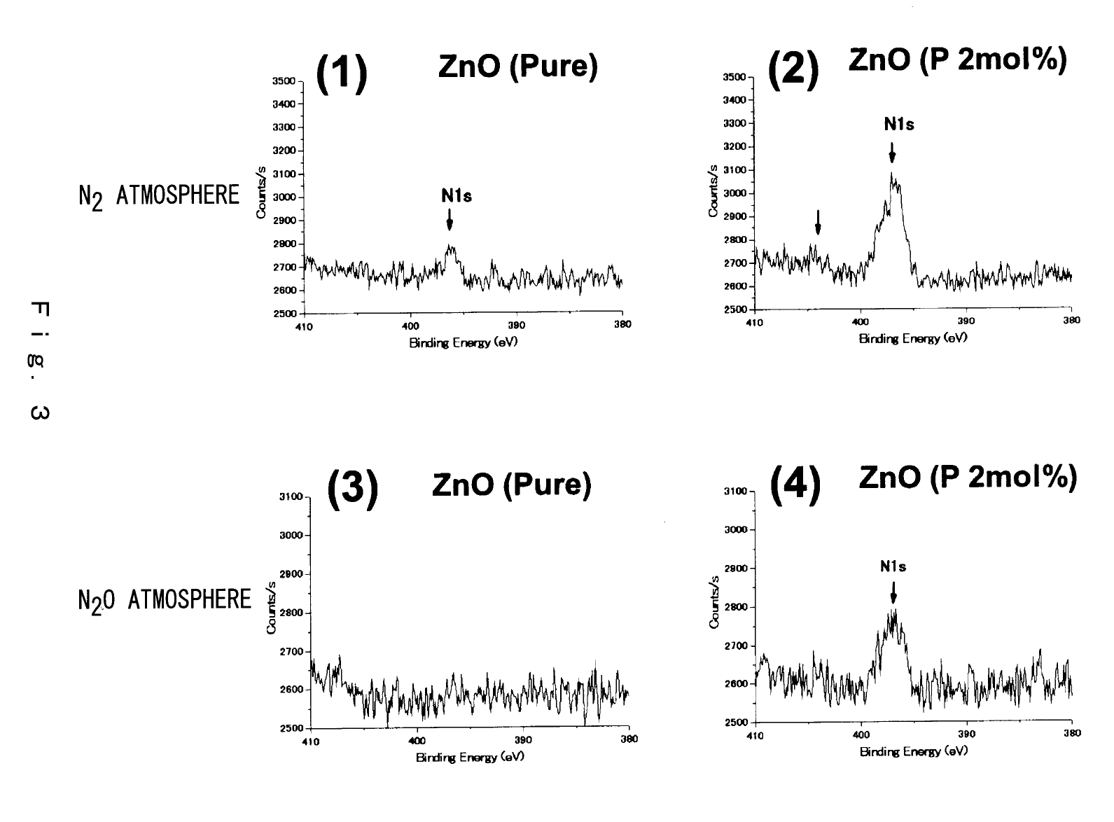

The atmosphere gas during film formation will preferably include nitrogen, which is a p-type dopant; nitrogen gas or a mixture of nitrogen gas and oxygen gas, nitrous oxide gas, ammonia gas, or the like can be used. However, zinc oxide thin films are not readily doped with nitrogen. FIGS. 3-(1) and 3-(3) show the results obtained in X-ray photoelectron spectroscopy of zinc oxide thin films produced in nitrogen atmosphere and nitrous oxide atmosphere using zinc oxide targets.

Based on the peaks that appeared for N is bond energy in films produced in a nitrogen atmosphere, it was clear that the films had been doped with nitrogen (FIG. 3-(1)). On the other hand, no peaks from N were observed in films produced in the nitrous oxide atmosphere (FIG. 3-(3)), and the nitrogen concentration in the films was under the detection threshold in X-ray photoelectron spectroscopy.

FIGS. 3-(2) and 3-(4) show the results obtained in X-ray photoelectron spectroscopy of zinc oxide thin films produced in nitrogen atmosphere and nitrous oxide atmosphere using zinc oxide targets to which 2 mol % phosphorus had been added. Pronounced peaks for N 1s bond energy appeared in thin films produced in the nitrogen atmosphere as well as thin films produced in the nitrous oxide atmosphere. It may thus be seen that simultaneous doping with phosphorus allowed the nitrogen content in thin films to be increased even in the nitrous oxide atmosphere.

Thin films produced at a substrate temperature of 500° C. in a nitrous oxide atmosphere using zinc oxide targets to which 2 mol % phosphorus had been added were annealed for 30 sec at 900° C. in an argon atmosphere (elevated temperature annealing) and then for 3.5 hours at 500 to 550° C. in an oxygen atmosphere (low temperature annealing). FIG. 4 shows the results for the Hole voltage-magnetic field dependency determined in the measurement of the Hall effect in these samples. Graphs of the Hall voltage-magnetic field properties were inclined toward the upper right in the same manner as the results in FIG. 2, thus showing that p-type zinc oxide thin films had been obtained. The resistivity at this time was 86.4 Ω·cm, and the Hall concentration was 4.40×1015 cm⁻³.

As these results show, in order to convert zinc oxide thin films to a p-type semiconductor, it is effective to simultaneously add nitrogen in combination another element such as phosphorus, as long as it does not interfere with the p-type conversion, in order to increase the nitrogen concentration in the thin film, in addition to adding just the element nitrogen, which is a p-type dopant, to thin films. Unless otherwise specified, all further results for the measurement of the Hall effect will be for samples that have been obtained by carrying out the annealing treatment of the invention on zinc oxide thin films to which nitrogen has been added by being prepared in a nitrous oxide atmosphere using a zinc oxide target to which phosphorus has been added.

The atmosphere gas during elevated temperature annealing may be any kind, provided that it is nitrogen gas or an inert gas. The results in FIG. 4 are from samples undergoing elevated temperature annealing in an argon gas atmosphere, which is an inert gas. FIG. 5 shows the results for measurement of the Hall effect in samples undergoing elevated temperature annealing in a nitrogen atmosphere instead or argon gas. That is, FIG. 5 shows the magnetic field dependence of the Hall voltage in measurement of the Hall effect in samples of the first embodiment of the invention obtained when zinc oxide thin films produced in a nitrous oxide atmosphere using zinc oxide targets to which 2 mol % phosphorus had been added were annealed for 30 sec at 900° C. in a nitrogen atmosphere (elevated temperature annealing) and then for 3.5 hours at 500 to 550° C. in an oxygen atmosphere (low temperature annealing). The results clearly showed the films to be p-type semiconductors in the same manner as in FIG. 4. The resistivity at this time was 32.3 Ω·cm, and the Hall concentration was 4.95×10¹⁵ cm⁻³.

On the other hand, when the elevated temperature annealing was carried out in an oxygen atmosphere, the thin film resistivity was extremely high, and the results of Hall effect measurements did not clearly show the conduction type. It was assumed that this was because the added nitrogen was replaced by oxygen, and that the excess zinc was reduced, resulting in a thin film that was almost entirely an insulator. The elevated temperature annealing for activating the p-type dopant must therefore be carried out in a nitrogen gas atmosphere or an inert gas atmosphere.

The relationship between elevated temperature annealing and temperature is shown below. The treatment time for the elevated temperature annealing in FIG. 4 is 30 seconds. Even with 1 min of elevated annealing at 900° C., the result of Hall effect measurement was a positive inclination in a graph of the Hall voltage-magnetic field properties, as shown in FIG. 6-(1), indicating a p-type semiconductor. However, 2 minutes of elevated temperature annealing at 900° C. resulted in a negative inclination in the graph of the Hall voltage-magnetic field properties, as shown in FIG. 6-(2), indicating that the film was an n-type semiconductor. This was attributed to the significant reduction in the level of p-type dopant in the film as a result of the longer annealing time because p-type dopants are gradually vaporized at the same time that they are activated in elevated temperature annealing.

The Hall effect properties of p-type semiconductors shown thus far were all obtained as a result of elevated temperature annealing followed by low temperature annealing at 500 to 550° C. in a 1 atm oxygen atmosphere. FIG. 7 shows the results obtained in measurement of the Hall effect in samples which, for the sake of comparison, had undergone elevated temperature annealing but no low temperature annealing. The elevated temperature annealing was for 30 sec at 900° C. in a nitrogen atmosphere.

As shown in FIG. 7, the negative inclination in the graph of the Hall voltage-magnetic field properties reveals an n-type semiconductor. The cause was attributed to the following. When a zinc oxide thin film to which a p-type dopant has been added is annealed in a reducing atmosphere such as an inert gas or nitrogen gas, oxygen is lost in the zinc oxide at the same time that the p-type dopant is activated, resulting in the production of greater amounts of excess zinc in the thin film. The excess zinc acts as a donor in the zinc oxide thin film, and films that undergo only elevated temperature annealing become n-type semiconductors.

The excess zinc produced in thin films during elevated temperature annealing can be effectively reduced through annealing at a temperature of 500 to 550° C. in an atmosphere containing oxygen (such as air or oxygen gas). As a result of the reduction of the excess zinc which is a source of donors, the electrical properties of p-type semiconductors can be developed based on acceptors activated in the elevated temperature annealing treatment. The time of the low temperature annealing will depend on the level of excess zinc in the thin film, film thickness, oxygen pressure in the atmosphere gas, and the like, but the treatment time is preferably as long as possible.

Samples which had undergone low temperature annealing but no elevated temperature annealing had extremely high resistivity, and measurement of the Hall effect using a Hall bar was unable to clearly shown the semiconductor conduction type. It was assumed that this was because the dopant which had been introduced as an acceptor was not activated, and excess zinc acting as a donor was virtually eliminated by the low temperature annealing treatment.

The above results show that, in order to develop the p-type electrical properties of zinc oxide thin films, it is necessary to combine the two steps of carrying out a treatment in which the p-type dopant is activated by elevated temperature annealing, and the excess zinc is then removed by low temperature annealing. The establishment of these steps in the present invention resulted in the development of a highly reliable p-type zinc oxide semiconductor thin film clearly shown through measurement of the Hall effect using a Hall bar to have p-type electrical properties.

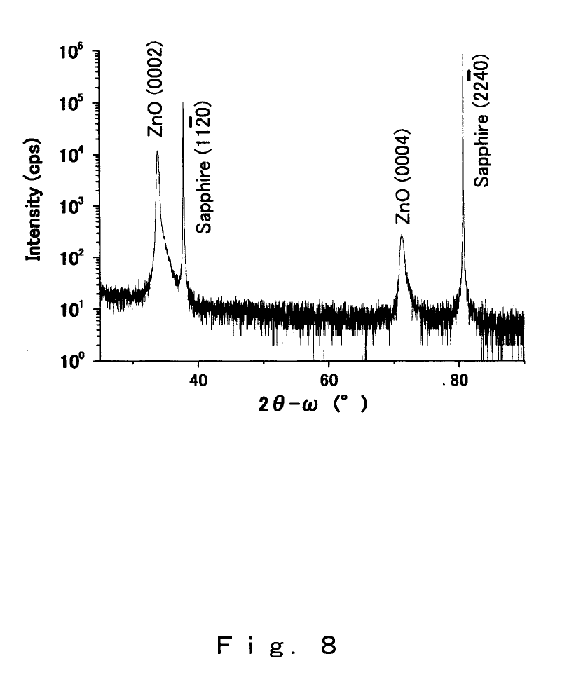

FIG. 8 shows the results of X-ray diffraction based on 2θ-ω scanning for a zinc oxide thin film produced in a nitrous oxide atmosphere using a zinc oxide target to which 2 mol % phosphorus had been added. Only (0001) diffraction lines for zinc oxide appeared other than diffraction lines for the sapphire substrate, revealing a c-axis oriented zinc oxide thin film. The 2θ-ω scan half-width of the (0002) diffraction line for zinc oxide was 0.33°, and the rocking curve (ω scan) half-width was 1.21°, with poor thin film crystallinity.

Nevertheless, the treatment according to the present invention results in a p-type zinc oxide thin film that has a low resistivity of no more than 100 Ω·cm. This shows that, for the conversion of zinc oxide to a p-type semiconductor, the film crystallinity has no significant effect, and that it is important to activate the p-type dopant by elevated temperature annealing and to control the excess zinc in the film by low temperature annealing.

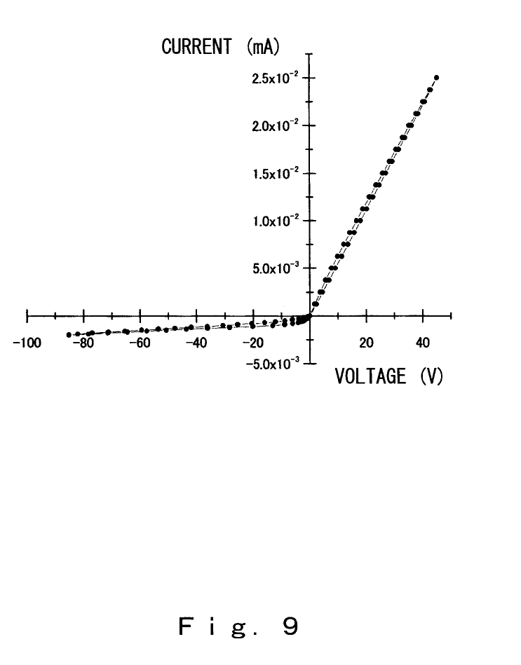

Lastly, FIG. 9 shows the current-voltage properties of p-n junctions in a p-type zinc oxide thin film according to the first embodiment of the invention laminated with a gallium-doped n-type zinc oxide thin film. The n-type zinc oxide thin film was deposited by laser ablation on a p-type zinc oxide thin film according to the present invention using a zinc oxide target to which to which 2 mol % gallium had been added as an n-type dopant. The current-voltage properties in FIG. 9 show that the current tended to flow in the forward direction, the current was less likely to flow in the reverse direction, indicating rectification properties characteristic of p-n junctions. These results serve as corroborating evidence that the zinc oxide thin film according to the invention is a p-type semiconductor.

### Example 2

This embodiment is a detailed illustration, based on the drawings, of an embodiment of a p-type zinc oxide thin film, in which a zinc oxide thin film is produced by pulse laser deposition on a sapphire substrate as the film is irradiated with active species produced through the creation of a plasma from nitrogen gas by RF (radio frequency) inductive coupling, and the resulting zinc oxide thin film, which has been doped while the nitrogen was in an activated state as an acceptor, is developed by a low temperature annealing treatment.

The zinc oxide thin film was produced by pulse laser deposition using KrF excimer laser light (wavelength 248 nm). Zinc oxide powder which had been compression molded into pellets and then sintered was used as the starting material zinc oxide target. The target was set up facing the substrate heater inside a vacuum vessel.

A sapphire monocrystalline substrate was secured to the surface of the substrate heater. The distance between the target and substrate was 50 mm. A vacuum was created in the vessel using a rotary pump and turbo-molecular pump, and after a pressure of 10⁻⁵ to 10⁻⁶ Pa had been reached, the substrate heater was heated to 400° C. to heat the substrate. The target surface was then irradiated with pulse laser light focused through a lens to vaporize the target and allow a zinc oxide thin film to be deposited on the substrate. The laser oscillating frequency was 2 Hz, and the energy was 60 mJ/pulse.

To dope the film with nitrogen as an acceptor, nitrogen gas was introduced at a flow rate of 0.3 sccm into a PBN (pyrolytic boron nitride) discharge tube, a 300 W RF (radio frequency) was then applied to produce a plasma, and the substrate surface was irradiated with an active species of nitrogen through a φ 0.2 mm×25 hole aperture as the film was formed. Oxygen gas was also simultaneously introduced at a flow rate of 0.6 sccm into the vacuum vessel. The pressure in the vessel at that time was ≦1.9×10⁻² Pa.

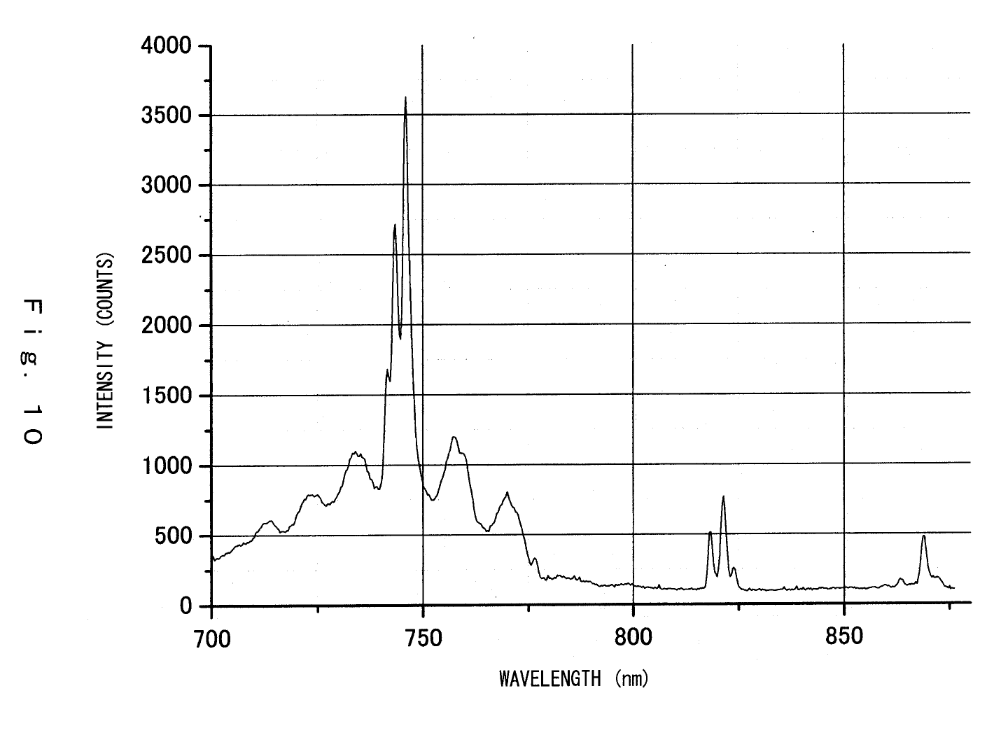

FIG. 10 illustrates the optical spectra in the discharge tube when the active species was produced by RF (radio frequency) plasma discharge to dope the film with nitrogen as the p-type dopant in the present embodiment. Sharp peaks appeared around wavelengths 745 nm, 821 nm, and 869 nm indicate radiation from nitrogen atoms and that active species of nitrogen had been produced.

The Hall effect was measured using a Hall bar to clearly show whether the resulting film was a p-type semiconductor or n-type semiconductor. The details were as shown in Example 1 above.

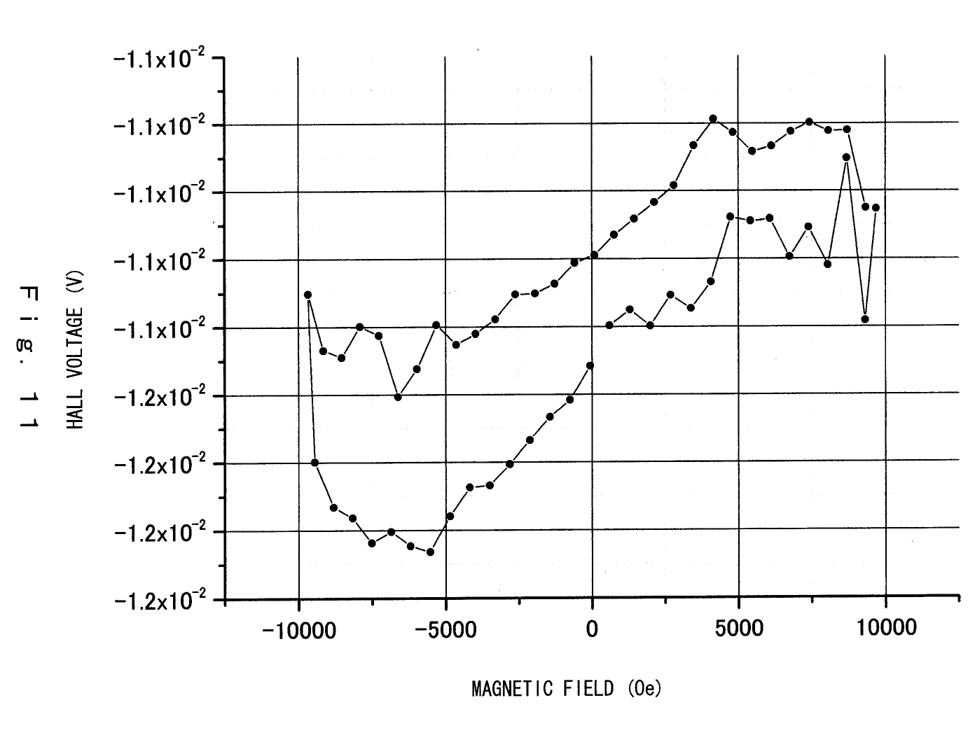

FIG. 11 illustrates the results obtained in measurement of the Hall effect in a sample which was obtained upon 3 hours of annealing at 550° C. in an oxygen atmosphere (low temperature annealing) of a zinc oxide thin film that was produced by pulse laser deposition on a sapphire substrate while irradiated with active species of nitrogen produced by RF (radio frequency) radiation. The inclination in the graph of the Hall voltage-magnetic field properties clearly showed the film to be a p-type semiconductor. The resistivity was 23.7 Ω·cm, the carrier concentration was 3.98×10¹⁶ cm⁻³, and the mobility was 3.71×10⁻¹ cm²/V·s.

### INDUSTRIAL APPLICABILITY

As described above, the present invention, which is related to a p-type zinc oxide thin film and its method of production, can provide a method for producing a p-type zinc oxide thin film on a transparent substrate such as a sapphire substrate, which is necessary when using zinc oxide to produce light-emitting elements that emit light of wavelengths ranging from blue to across the UV spectrum, as well as the resulting highly reliable p-type zinc oxide thin films and light-emitting elements. According to the present invention, it is also possible to provide a carrier control technique which can serve as the basis for techniques related to transparent semiconductor films or wide band gap semiconductor electronics in which zinc oxide is employed.

1. A p-type zinc oxide semiconductor thin film, characterized in that 1) a p-type dopant added to the thin film is in an activated state, 2) excess zinc is removed, 3) the inclination in a graph of Hall voltage-magnetic field properties in results for Hall effect measurements clearly reveals the film to be a p-type semiconductor, and 4) whereby conversion to a p-type semiconductor is realized.

2. The p-type zinc oxide semiconductor thin film according to claim 1, characterized in that the magnetic field dependence of the Hall voltage in measurement of the Hall effect using a Hall bar clearly reveals that the film is a p-type semiconductor.

3. The p-type zinc oxide semiconductor thin film according to claim 1, comprising a substrate, the p-type zinc oxide semiconductor thin film being characterized in that the substrate is a glass substrate, sapphire substrate, zinc oxide monocrystalline substrate, or a substrate having a zinc oxide monocrystalline thin film on a surface layer thereof, regardless of crystal symmetry or compatibility of lattice constant with the p-type zinc oxide thin film to be formed thereon.

4. The p-type zinc oxide semiconductor according to claim 1, characterized in that the zinc oxide thin film converted to a p-type is a monocrystalline (epitaxial) thin film or polycrystalline thin film.

5. The p-type zinc oxide semiconductor thin film according to claim 1, characterized in that the Hall concentration is at least 1×10¹⁵ cm⁻³.

6. The p-type zinc oxide semiconductor thin film according to claim 1, characterized in that the electrical resistivity is not more than 100 Ω·cm.

7. A method for producing a p-type zinc oxide semiconductor thin film, characterized by combining a step for activating a p-type dopant added to a zinc oxide thin film in order to develop p-type semiconductor properties of zinc oxide, and a step for low temperature annealing in an oxidizing atmosphere, whereby conversion to a p-type semiconductor is realized.

8. The method for producing a p-type zinc oxide semiconductor thin film according to claim 7, characterized in that the thin film is annealed at a high temperature of 700 to 1200° C. in an inert gas atmosphere or nitrogen gas atmosphere as the step for activating the p-type dopant added to the zinc oxide thin film.

9. The method for producing a p-type zinc oxide semiconductor thin film according to claim 7, characterized in that the substrate surface is irradiated with an active species of dopant so that the thin film is doped while the p-type dopant is activated during the step of growing the zinc oxide thin film as the step for activating the p-type dopant added to the zinc oxide thin film.

10. The method for producing a p-type zinc oxide semiconductor thin film according to claim 7, characterized in that the thin film is annealed at a low temperature of 200 to 700° C. in an oxidizing atmosphere as the low temperature annealing step.

11. The method for producing a p-type zinc oxide semiconductor thin film according to claim 7, characterized in that nitrogen is used as the p-type dopant for converting the zinc oxide to a p-type, and this is added either alone or with another element.

12. A light-emitting element, comprising a structure in which the p-type zinc oxide thin film according to any of claims 1 to 6 is formed on a substrate.

13. The light-emitting element according to claim 12, comprising a structure in which a monocrystalline (epitaxial) thin film or polycrystalline thin film is formed on a glass substrate, sapphire substrate, zinc oxide monocrystalline substrate, or a substrate having a zinc oxide crystalline thin film on a surface thereof.
